(19) United States
(12) Patent Application Publication
(10) Pub. No.: US 2016/0142660 A1
(43) Pub. Date: May 19, 2016

(54) SINGLE CHIP IMAGE SENSOR WITH BOTH VISIBLE LIGHT IMAGE AND ULTRAVIOLET LIGHT DETECTION ABILITY AND THE METHODS TO IMPLEMENT THE SAME

(71) Applicants: Yanfei Shen, San Jose, CA (US); Guangbin Zhang (Garry), Cupertino, CA (US); Wenhao Qiao, Milpitas, CA (US); Jiangtao Pang, Fremont, CA (US); Zheng Du, San Jose, CA (US)

(72) Inventors: Yanfei Shen, San Jose, CA (US); Guangbin Zhang (Garry), Cupertino, CA (US); Wenhao Qiao, Milpitas, CA (US); Jiangtao Pang, Fremont, CA (US); Zheng Du, San Jose, CA (US)

(73) Assignee: CISTA SYSTEM CORP., San Jose, CA (US)

(21) Appl. No.: 14/853,948

(22) Filed: Sep. 14, 2015

Related U.S. Application Data
(60) Provisional application No. 62/049,362, filed on Sep. 12, 2014.

(51) Int. Cl. H04N 5/369; H04N 9/04; H01L 27/146; H04N 5/361

(52) U.S. Cl. CPC H04N 5/369; H04N 5/361; H04N 9/045; H01L 27/14685; H01L 27/1462

(57) ABSTRACT

The present invention relates to a single chip image sensor with both visible light image and ultraviolet light detection ability and methods to implement the single chip image sensor. In an embodiment, a single chip image sensor may comprise a first plurality of sensor cells provided on a substrate, the first plurality of sensor cells each including a photo detector sensitive to visible light, and a UV coating layer provided for the first plurality of sensor cells to convert incident UV light to visible light.

### CROSS-REFERENCE TO RELATED U.S. APPLICATIONS

This application claims the benefit of, and priority to, U.S. Provisional Patent Application Ser. No. 62/049,362, entitled “Single chip image sensor with both visible light image and ultraviolet light detection ability and the methods to implement the same”, and filed on Sep. 12, 2014, the entire content of which is incorporated herein by reference for all purposes.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### FIELD OF THE INVENTION

The present invention generally relates to solid state image sensor, and more particularly, to an image sensor that integrates both visible light image and ultraviolet light detection ability into one single chip, and methods to implement the single chip image sensor.

### BACKGROUND OF THE INVENTION

Visible light image sensor is normally used for taking pictures and videos at visible light scene. Ultraviolet (UV) light sensor is normally used to detect ultraviolet radiation other than visible light. Both types of sensors have been widely used in various fields. For example, visible light image sensors have been used in digital cameras and mobile phones integrated with a camera module, and UV sensors have been used for military purposes or industrial applications. Now most of the commercially available UV sensors are in separate modules, while typical visible light image sensors are not able to sense UV light on the same chip. There are also specialized UV image sensors that can take UV images, but they cannot take a visible light image. Typically, a color filter or a film coating is used above a silicon based image sensor to make it sensitive to certain band of light spectrum. For visible light image sensors, the color filter will pass only light in visible spectrum to the sensor, thus any light outside of visible spectrum, including UV light, will be blocked. This causes difficulty to integrate both visible light and UV sensitivity into one single chip.

Today, mobile devices have been widely used, and preferably they can be more compact in size and more functional in utility. A single chip visible light image sensor combined with UV light sensor can enable additional functions in mobile devices. For example, people can use the UV light sensor to check the UV radiation during outdoor activities, and determine how much sunscreen he/she needs to apply. Currently these two types of functions are realized by a separate visible light image sensor and a separate UV sensor module. In contrast to mobile device with a separate UV sensor module, a single chip solution can make the system more compact and lower down the overall system cost. Generally, integrating more components into one single chip is important in integrated circuit design to achieve lower power consumption, higher yield, lower cost, smaller area, and easier board and system level integration.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY OF THE INVENTION

Advantageously, the present invention provides an image sensor that integrates both visible light image and ultraviolet light detection ability into one single chip. As compared with a solution that includes a separate visible light image sensor and a separate UV sensor module, the single chip image sensor of the present invention is more compact and cost effective. The present invention also provides methods to implement the single chip image sensor.

An aspect of the present invention provides a single chip image sensor that comprises a first plurality of sensor cells provided on a substrate. Each of the first plurality of sensor cells may include a photo detector sensitive to visible light. The single chip image sensor may further comprise a UV coating layer provided for the first plurality of sensor cells to convert incident UV light to visible light.

In some embodiments, the single chip image sensor may further comprise a second plurality of sensor cells provided on the substrate. Each of the second plurality of sensor cells also include a photo detector sensitive to visible light.

In some embodiments, the single chip image sensor may further comprise a filter film disposed on the UV coating layer to block incident visible and infrared lights.

In some embodiments, the single chip image sensor may further comprise a package cover disposed over the first and second plurality of sensor cells.

In some embodiments, the UV coating layer may be provided on a portion of the package cover that covers the first plurality of sensor cells.

In some embodiments, the UV coating layer may be provided between the package cover and the first plurality of sensor cells.

In some embodiments, the first and second plurality of sensor cells each further comprises a color filter formed on the photo detector to allow light of a particular color to pass therethrough, and a micro-lens formed on the color filter to focus incident light onto the photo detector. In some embodiments, the color filter includes a red, green or blue filter.

In some embodiments, the UV coating layer may be formed within the first plurality of sensor cells. The color filters in the first plurality of sensor cells are replaced by the UV coating layer.

In some embodiments, the first and second plurality of sensor cells are arranged in an array of a rectangular shape. The first plurality of sensor cells are arranged along a side of the rectangular shape.

In some embodiments, the second plurality of sensor cells may include a black region where the sensor cells are covered by a black layer so as to sense a dark current. The first plurality of sensor cells and the second plurality of sensor cells in the black region are arranged along a same side of the rectangular shape.

In some embodiments, the first and second plurality of sensor cells share a same readout circuit.

In some embodiments, the second plurality of sensor cells are arranged in a rectangular region that is separated from or abuts a rectangular region where the first plurality of sensor cells are arranged.

Another aspect of the present invention provides an electronic device having an imaging function. The electronic device may include a single chip image sensor that comprises a first plurality of sensor cells provided on a substrate. The first plurality of sensor cells each include a photo detector sensitive to visible light. The single chip image sensor may further comprise a UV coating layer provided for the first plurality of sensor cells to convert incident UV light to visible light.

In some embodiments, the electronic device may further comprise a second plurality of sensor cells provided on the substrate, and the second plurality of sensor cells each also include a photo detector sensitive to visible light.

In some embodiments, the electronic device may further comprise a filter film disposed on the UV coating layer to block incident visible and infrared lights.

In some embodiments, the electronic device may further comprise a package cover disposed over the first and second plurality of sensor cells. The UV coating layer may be disposed above or below the package cover.

In some embodiments, the electronic device may be one of a cell phone, a tablet, a laptop, a personal digital assistant (PDA), a wearable device such as a smart watch, or a camera.

Yet another aspect of the present invention provides a method of making a single chip image sensor. The method may comprise steps of forming a first plurality of sensor cells on a substrate, the first plurality of sensor cells each including a photo detector sensitive to visible light, and providing a UV coating layer for the first plurality of sensor cells, the UV coating layer being capable of converting incident UV light to visible light.

In some embodiments, the method may further comprise a step of forming a second plurality of sensor cells on the substrate. The second plurality of sensor cells may each also include a photo detector sensitive to visible light.

In some embodiments, the first and second plurality of sensor cells may be formed on the substrate in the same process.

In some embodiments, the method may further comprise a step of providing a filter film on the UV coating layer. The filter film is capable of blocking incident visible and infrared lights.

In some embodiments, the method may further comprise a step of providing a package cover over the first and second plurality of sensor cells. The UV coating layer may be disposed above or below the package cover.

In some embodiments, the step of forming the first and second plurality of sensor cells may include forming the plurality of photo detectors on the substrate, forming a plurality of color filters on the plurality of photo detectors, respectively, and forming a plurality of micro-lens on the plurality of color filters, respectively.

The above features and advantages and other features and advantages of the present invention are readily apparent from the following detailed description of the best modes for carrying out the invention when taken in connection with the accompanying drawings.

### BRIEF DESCRIPTION OF THE SEVERAL VIEWS OF THE DRAWINGS

The present invention is illustrated by way of example, and not by way of limitation, in the figures of the accompanying drawings and in which like reference numerals refer to similar elements. All the figures are schematic and generally only show parts which are necessary in order to elucidate the invention. For simplicity and clarity of illustration, elements shown in the figures and discussed below have not necessarily been drawn to scale. Well-known structures and devices are shown in simplified form such as block diagrams in order to avoid unnecessarily obscuring the present invention. Other parts may be omitted or merely suggested.

FIG. 1 is a schematic diagram showing a single chip image sensor that integrates both visible light image and ultraviolet light detection ability into one single chip, in accordance with an exemplary embodiment of the present invention.

FIG. 2 is a schematic cross section view showing a single chip image sensor in accordance with an exemplary embodiment of the present invention.

FIG. 3A illustrates a step wherein a plurality of photo detectors are formed on a substrate in a method of implementing a single chip image sensor in accordance with an exemplary embodiment of the present invention.

FIG. 3B illustrates a step wherein a plurality of color filters are formed on the photo detectors in a method of implementing a single chip image sensor in accordance with an exemplary embodiment of the present invention.

FIG. 3C illustrates a step wherein a plurality of microlens are formed on the color filters in a method of implementing a single chip image sensor in accordance with an exemplary embodiment of the present invention.

FIG. 3D illustrates a step wherein a package cover is attached to an image sensor structure in a method of implementing a single chip image sensor in accordance with an exemplary embodiment of the present invention.

FIG. 3E illustrates a step wherein an UV coating layer and a filter layer are formed on the package cover in a method of implementing a single chip image sensor in accordance with an exemplary embodiment of the present invention.

FIG. 4 is a schematic cross section view showing a single chip image sensor in accordance with another exemplary embodiment of the present invention.

FIG. 5A illustrates a step wherein a plurality of color filters are formed on photo detectors in a method of implementing a single chip image sensor in accordance with another exemplary embodiment of the present invention.

FIG. 5B illustrates a step wherein a UV coating layer and a filter layer are formed on the photo detectors in a method of implementing a single chip image sensor in accordance with another exemplary embodiment of the present invention.

FIG. 5C illustrates a step wherein a plurality of sensor cells are formed in a method of implementing a single chip image sensor in accordance with another exemplary embodiment of the present invention.

FIG. 5D illustrates a step wherein a single chip image sensor is formed in a method of implementing a single chip image sensor in accordance with another exemplary embodiment of the present invention.

FIG. 6 is a schematic diagram showing several options to combine the visible and UV sensors into one single chip, in accordance with exemplary embodiments of the present invention.

FIG. 7 is a schematic chart showing an example of the data transmission format combining visible and UV image data.

### DETAILED DESCRIPTION OF THE PREFERRED EMBODIMENT

In the following description, for the purposes of explanation, numerous specific details are set forth in order to provide a thorough understanding of the present invention. It is apparent, however, to one skilled in the art that the present invention may be practiced without these specific details or with an equivalent arrangement.

It is also to be understood that the terminology used herein is for the purpose of describing particular embodiments only, and is not intended to limit the scope of the invention. For example, when an element is referred to as being “on”, “connected to”, or “coupled to” another element, it can be directly on, connected or coupled to the other element or intervening elements may be present. In contrast, when an element is referred to as being “directly on”, “directly connected to”, or “directly coupled to” another element, there are no intervening elements present.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

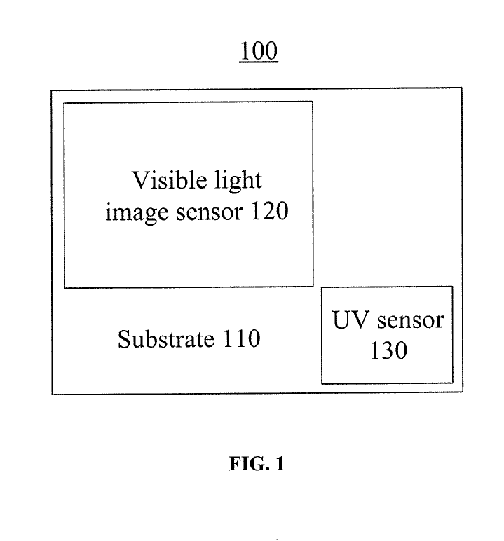

FIG. 1 is a schematic diagram showing an image sensor 100 that integrates both visible light image and ultraviolet light detection ability into one single chip, in accordance with an exemplary embodiment of the present invention. Referring to FIG. 1, the single chip image sensor 100 includes a visible light image sensor 120 and an UV sensor 130 that are formed on a single substrate 110.

The substrate 110 may be a typical semiconductor substrate that can be used to build an image sensor thereon. Examples of materials suitable for the substrate 110 include, but are not limited to, Si, Ge, SiGe, SiC, GaAs, InP, and the like. The substrate 110 may also be an insulating substrate made of, for example, glass or plastic, on which semiconductor materials such as Si or SiC may be deposited to form image sensors such as photo diodes which will be described in detail later. The visible light image sensor 120 and the UV sensor 130 may be image sensors of any types. For example, they could be CCD sensors, CMOS sensors, or the like. Preferably, the visible light image sensor 120 and the UV sensor 130 are of the same type. In some embodiments, they both could be CCD sensors or CMOS sensors. The same type of sensors 120 and 130 would simplify the process to integrate them on the substrate 110 and thus increase product yield and reduce cost of the chip 100. The process to form the sensors 120 and 130 will be discussed in detail later.

Although FIG. 1 shows that the visible light image sensor 120 and the UV sensor 130 are arranged on the substrate 110 separated from each other, they could also be laid on the substrate 110 in other patterns. In some embodiments, the visible light image sensor 120 and the UV sensor 130 may be integrated into a rectangular region. In this case, the substrate 110 may be sized smaller, the chip 100 may be more compact, and it would be easier to read out image data from the sensors 120 and 130 as discussed in detail later.

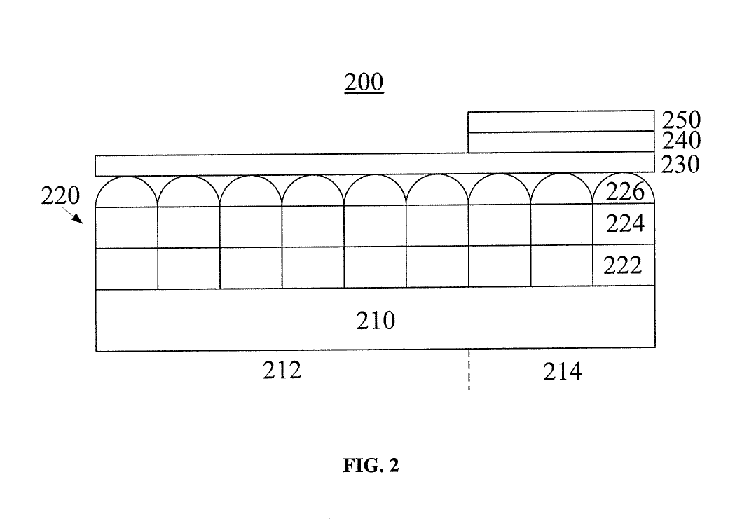

Now turning to FIG. 2, there is shown a schematic cross section view of a single chip image sensor 200 in accordance with an exemplary embodiment of the present invention. The image sensor chip 200 may include a single substrate 210, which may be a semiconductor substrate that is conventionally used to build an image sensor thereon. Examples of typical semiconductor materials suitable for the substrate 210 include, but are not limited to, Si, Ge, SiGe, SiC, GaAs, InP, and the like. In some embodiments, the substrate 210 may be a crystal Si or poly-Si substrate. The substrate 210 may be divided into a visible light sensing section 212 and a UV sensing section 214. Although FIG. 2 shows that the visible light sensing section 212 and the UV sensing section 214 abut each other, in some embodiments they may be separated from each other by a distance.

A plurality of image sensor cells 220 are formed on the substrate 210 in both the visible light sensing section 212 and the UV sensing section 214. The plurality of image sensor cells 220 may be any types of image sensors. For example, the sensor cells 220 may be CCD sensors, CMOS sensors, or the like. Preferably, all the sensor cells 220 are of the same type, no matter they are formed in the visible light sensing section 212 or the UV sensing section 214. Thus, the sensor cells 220 may be formed by a single process in the visible light sensing section 212 or the UV sensing section 214.

The plurality of image sensor cells 220 each may include a photo detector 222 to detect light in a certain band of light spectrum. In some embodiments, the photo detectors 222 are all formed to be sensitive to visible light, even in the UV sensing section 214 of the substrate 210. The photo detectors 222 may be formed of, for example, a photo diode that includes a PN junction of a N-type impurity diffusion region formed in a P-type well of the Si substrate 210. The photo diode may absorb visible light and convert photons to electrons, which are then extracted as a detection signal. FIG. 2 schematically shows that the plurality of photo detectors 222 are closely adjacent to each other, though they may be spaced apart from each other. In this case, there may be some elements or circuits to drive the photo detectors 222 formed in the substrate 210 between the photo detectors 222. For example, when the chip 200 is designed as a CCD sensor chip, a shift register may be formed between adjacent photo detectors 222; and when the chip 200 is designed as a CMOS sensor chip, a transfer transistor and/or an amplifier transistor may be formed in the substrate 210 between adjacent photo detectors 222. Since CCD and CMOS sensors are already well known in the art, a detailed discussion on their configurations will be omitted here.

To get a colorful visible light image, color filters 224 may be provided on the photo detectors 222. The color filters 224 are provided at least on the photo detectors 222 formed in the visible light sensing section 212 of the substrate 210 where a visible light image will be captured. In the embodiment shown in FIG. 2, the color filters 224 may be provided on all of the plurality of photo detectors 222 formed in both the visible light sensing section 212 and the UV sensing section 214. Each of the color filters 224 may allow a particular color of light to pass therethrough, and it blocks light of other colors or wavelengths. In some embodiments, the color filters 224 may include red, green, and blue (RGB) filters that are arranged in a predetermined pattern. For example, the red, green and blue filters may repeat in this order in a row or column direction. In some other embodiments, the color filters 224 may also include yellow, magenta and cyan (YMC) filters.

Although not shown in FIG. 2, there may be other films or layers disposed between the color filters 224 and the photo detectors 222. In some embodiments, a wiring layer may be provided between the color filters 224 and the photo detectors 222, which includes wirings and/or interconnections disposed in an insulating film to connect elements and/or devices formed on the substrate 210. The insulating film may be made of transparent insulating materials. In some embodiments, it may be formed of inorganic insulators such as SiO₂. The wirings and interconnections may be formed of conductive metals such as Cu, and they are preferably positioned above between adjacent photo detectors 222 so as not to block light incident onto the photo detectors 222.

A plurality of microlens 226 may be provided on each of the color filters 222. The microlens 226 may focus incident light onto the photo detectors 222, thereby increasing amount of light sensed by the photo detectors 222. Thus, the microlens 226 may improve sensitivity and SNR (signal-noise ratio) of the chip 200. In some embodiments, the microlens 226 may be formed of transparent organic materials such as photoresist.

A package cover 230 may be stacked on the color filters 226 to protect the image sensor cells 220 therebelow from damages caused by scratches or impacts and from corrosion due to oxygen and moisture in the environment. In some embodiments, the package cover 230 may be made of transparent materials such as glass and plastic.

To incorporate an UV detection ability in the UV sensing section 214, in some embodiments, a UV coating layer 240 may be disposed on the package cover 230. As shown in FIG. 2, the UV coating layer 240 may be disposed on the package cover 240 only in the UV sensing section 214. The UV coating layer 240 may convert the incident light in UV spectrum band to visible light spectrum band. As known, visible light has a wavelength in a range of 380-780 nm, and UV light has a wavelength in a range of less than 380 nm. That is, UV light has larger energy than visible light. It has been found that some materials may be excited by light of higher energy (shorter wavelength) and emit light of lower energy (longer wavelength), which are also called as “down conversion materials”. Examples of down conversion materials that can absorb UV light and emit visible light include, for example, Lumogen, coronene, AlQ₃, ZnS:Mn, and the like.

By the UV coating layer 240 converting UV light into visible light, the image sensor cells 220 positioned in the UV sensing section 214 may sense the UV light, while the image sensor cells 220 positioned in the visible light sensing section 212 may still sense the visible light. Thus, the single chip image sensor 200 can sense both UV light and visible light. In some embodiments, the UV coating layer 240 may cover all the sensor cells 220 on the substrate 210 so that the chip 200 functions only as an UV image sensor chip.

In some cases, the visible light and/or infrared (IR) light can pass through the UV coating layer 240 and impinge on the photo detectors 222 in the UV sensing section 214, which may adversely affect detection of the UV light. To avoid this, a filter layer 250 may be provided on the UV coating layer 240 to block incident light spectrum of visible light and IR light range while passing the UV light. In some embodiments, the filter layer 250 may be a single layer. In some embodiments, the filter layer 250 may includes a stack of two or more laminated layers.

With the filter layer 250, the visible light and the IR light are blocked in the UV sensing section 214, and only the UV light passes through the filter layer 250 and impinges on the UV coating layer 240 where the UV light is converted into visible light. Then, the resulting visible light may be focused by the microlens 226 through the color filters 224 onto the photo detectors 222 in the UV sensing section 214. In some embodiments, the color filters 224 in the UV sensing section 214 may be replaced by a transparent layer. It is important to note that the filter layer 250 is only disposed on the UV coating layer 240 in the UV sensing section 214, so as not to influence operation of the sensor cells 220 in the visible light sensing section 212.

In some embodiments, the filter layer 250 may be omitted. In this case, some visible light and IR light may pass through the UV coating layer 240 and impinge on the photo detectors 222 in the UV sensing section 214. To avoid or reduce influence of such visible and IR light in the UV sensing section 214, light strength sensed by photo detectors 220 around or adjacent to the UV sensing section 214 will be read out and subtracted from the light strength sensed by photo detectors 220 within the UV sensing section 214, so that a real UV part of the light strength sensed by the photo detectors 220 in the UV sensing section 214 can be calculated. In some embodiments, the calculation may further consider transmission coefficient of the visible and IR light in the UV coating layer 240. For example, when the transmission coefficient is X where X is larger than zero and smaller than one, the light strength sensed by photo detectors 220 around or adjacent to the UV sensing section 214 can be multiplied by X before being subtracted from the light strength sensed by the photo detectors 220 within the UV sensing section 214, thereby further improving accuracy of the UV light detection.

Although FIG. 2 shows that the UV coating layer 240 is placed above the package cover 230, it can also be positioned differently. In some embodiments, the UV coating layer 240 may be placed below the package cover 230. For example, the UV coating layer 240 may be placed between the package cover 230 and the microlens 226 of the image sensor cells 220 in the UV sensing section 214. In this case, the package cover 230 may also protect the UV coating layer 240 from corrosion and pollution from environment, and reduce aging of the UV coating layer 240 over time, thereby increasing lifespan of the UV coating layer 240. The filter layer 250 may be placed above the package cover 230 opposite to the UV coating layer 240, or be placed between the package cover 230 and the UV coating layer 240 therebelow. When the UV coating layer 240 only or both the UV coating layer 240 and the filter layer 250 are placed below the package cover 230 in the UV sensing section 214, a planarization layer (not shown) may be provided on the microlens 226 in the visible light sensing section 212. The planarization layer may have an upper surface substantially flush with the upper surface of the UV coating layer 240 or the filter layer 250 so as to provide a flat surface to securely bear the package cover 230 provided thereon. In some embodiments, the planarization layer may be formed of a transparent material such as SiO₂.

In the embodiments discussed above, all the image sensor cells 220 may be formed to be sensitive to visible light. So, all the image sensor cells 220 may be formed in a same process. By providing the UV coating layer 240 in the UV sensing section 214 to convert the UV light to the visible light that can be sensed by the image sensor cells 220, the chip 200 can achieve both visible light image (in the visible light sensing section 212) and UV detection ability (in the UV sensing section 214) with a simple structure.

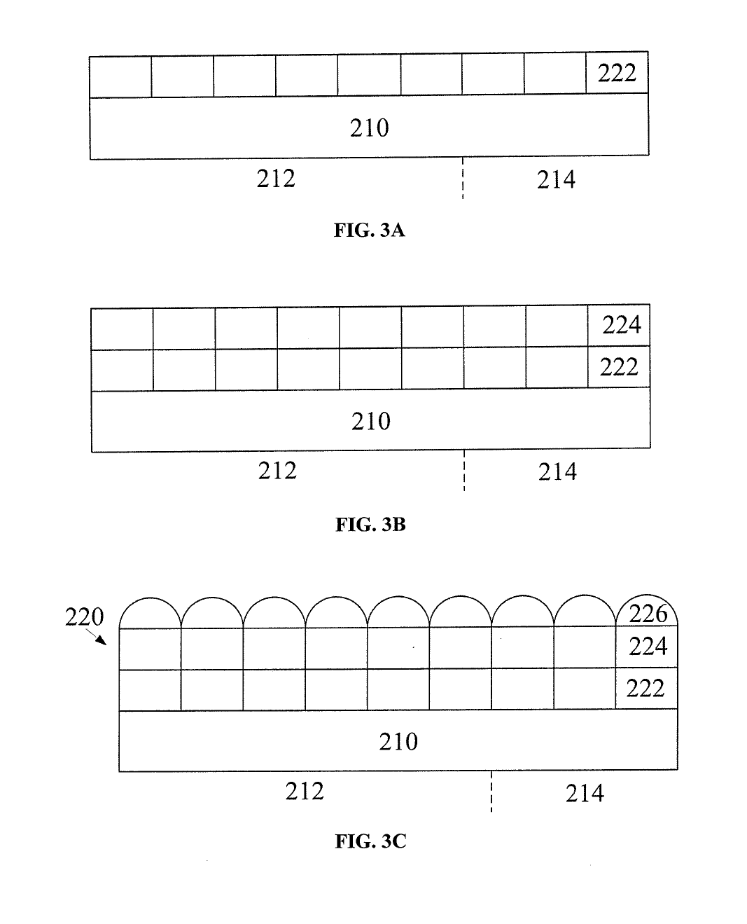

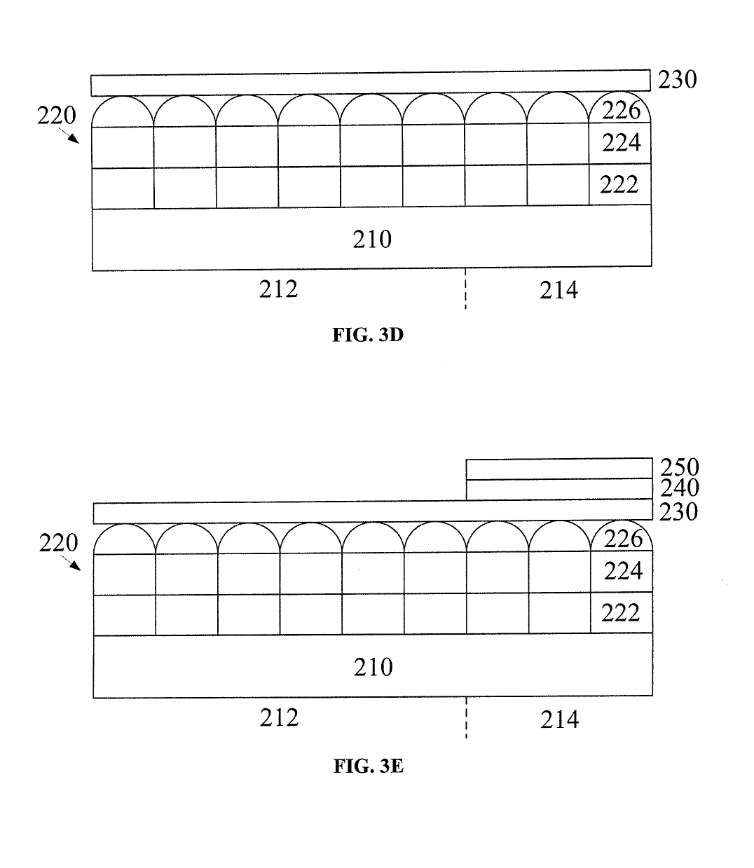

FIGS. 3A-3E are respectively process diagrams showing a method of implementing the single chip image sensor 200 as shown in FIG. 2, in accordance with an exemplary embodiment of the present invention. Referring to FIG. 3A first, a plurality of photo detectors 222 may be formed on a substrate 210. The substrate 210 includes a visible light sensing section 212 and an UV sensing section 214. Although FIG. 3A shows that the visible light sensing section 212 and the UV sensing section 214 abut each other, in some embodiments they may be separated from each other by a distance. As discussed above with reference to FIG. 2, the photo detectors 222 may include photo diodes formed of a PN junction within a Si substrate. Although not shown, the photo detectors 222 may be spaced apart from each other and some elements or circuits may be formed in the substrate 210 between the photo detectors 222 to drive or cooperate with the photo detectors 222 so as to extract electric signals therein.

Then, a plurality of color filters 224 may be formed on the photo detectors 222 as shown in FIG. 3B. The color filters 224 may include RGB or YMC filters, which may be formed by, for example, ink jetting or screen printing of dye. In the embodiment shown in FIG. 3B, the color filters 224 are formed on all the photo detectors 222. In some embodiments, the color filters 224 may be formed on only the photo detectors 222 in the visible light sensing section 212, and a transparent layer may be provided in the UV sensing section 214.

Next, a plurality of microlens 226 may be formed on the color filters 224, as shown in FIG. 3C. The microlens 226 may be formed by, for example, a thermal reflow process. In detail, a photoresist film may be applied by spin-coating on the color filters 224 and then subjects to exposure and development, forming a plurality of micro-cylinders on each of the color filters 224 respectively. Next, the micro-cylinders may be baked on a heating plate or in an oven at an optimum temperature for a predetermined time such that the photoresist melts and reflows. Due to surface tension, the cylinders will become a hemispherical shape, and the hemispherical shape will remain when the photoresist cools down, generating an array of microlens 226. Other methods for forming the microlens 226 are also possible, for example, a grey mask process, which is well known in the art and a detailed description thereof will be omitted here.

So far a plurality of image sensor cells 220 have been formed on the substrate 210. Then, referring to FIG. 3D, a package cover 230 may be attached to the top surface of the resulting structure. The package cover 230 may be a thin sheet of glass or plastic which is fabricated separately and then attached onto the sensor cells 220. Next, an UV coating layer 240 and a filter layer 250 may be formed in this order on a part of the package cover 230 corresponding to the UV sensing section 214 of the substrate 210, as shown in FIG. 3E, producing a single chip image sensor the same as that shown in FIG. 2. In some embodiments, the UV coating layer 240 and the filter layer 250 may be formed by coating a UV coating film on the package cover 230 and a filter film on the UV coating film, masking a part of the two films in the UV sensing section 214 with photoresist, and removing the rest of the two films in the visible light sensing section 212. In some embodiments, the UV coating layer 240 and the filter layer 250 may be formed by masking a part of the package cover 230 corresponding to the visible light sensing section 212 and depositing the UV coating layer 240 and the filter layer 250 directly on the rest of the package cover 230. In some embodiments, the UV coating layer 240 and the filter layer 250 may be formed in advance onto the package cover 230, and then the package cover 230 with the UV coating layer 240 and the filter layer 250 thereon is attached to the top surface of the plurality of sensor cells 220.

In some embodiments, the UV coating layer 240 and the filter layer 250 may be formed between the package cover 230 and the array of microlens 226 so that they can be protected by the package cover 230. In this case, the UV coating layer 240 and the filter layer 250 may be formed on the structure of FIG. 3C in the UV sensing section 214, and a transparent planarization layer (not shown) may be provided on the structure of FIG. 3C in the visible light sensing section 212. The planarization layer may have an upper surface substantially flush with the upper surface of the filter layer 250. Then, the package cover 230 may be attached to the resulting structure.

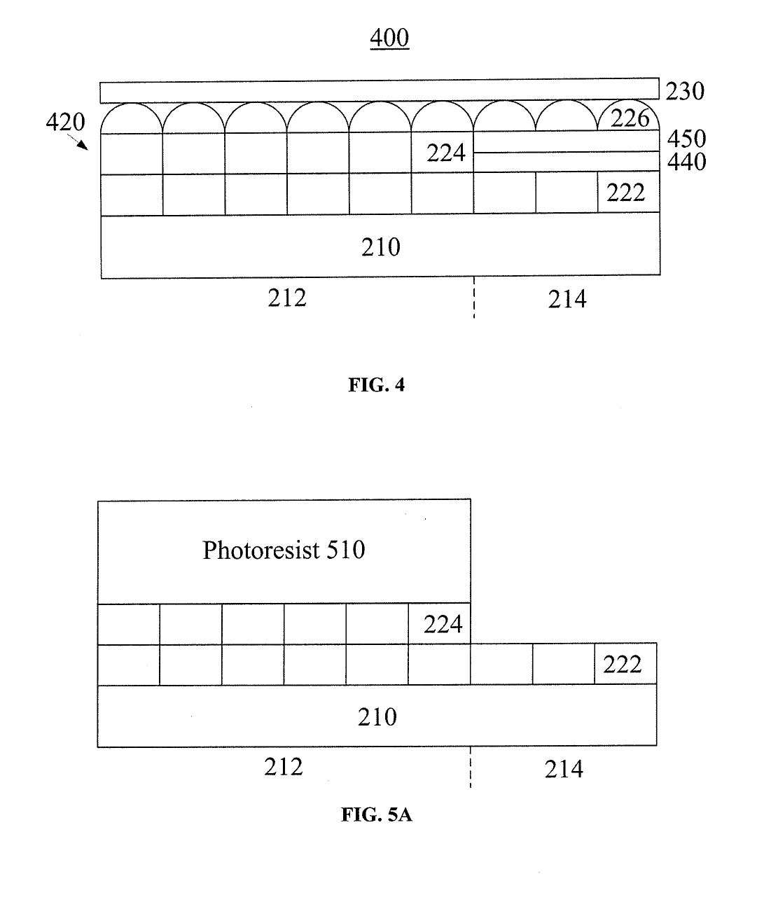

FIG. 4 is a schematic cross section view showing a single chip image sensor 400 in accordance with another exemplary embodiment of the present invention. The single chip image sensor 400 is generally similar to the single chip image sensor 200 as shown in FIG. 2 except that the UV coating layer and the filter layer are integrated within the image sensor cells. Elements similar to those shown in FIG. 2 are represented by similar reference signs and a repetitive description thereof will be omitted here.

Referring to FIG. 4, the image sensor chip 400 includes a single substrate 210 with a visible light sensing section 212 and a UV sensing section 214. A plurality of image sensor cells 420 are formed on the substrate 210 covering both the visible light sensing section 212 and the UV sensing section 214. The plurality of image sensor cells 420 each include a photo detector 222 formed on the substrate 210. Also, the photo detector 222 may include a PN junction sensitive to the visible light.

In the visible light sensing section 212, formed on the photo detectors 222 are a plurality of color filters 224. The color filters 224, however, are not formed in the UV sensing section 214. Instead, a UV coating layer 440 and a filter layer 450 are formed on the photo detectors 222 in the UV sensing section 214. Similar to the UV coating layer 240 shown in FIG. 2, the UV coating layer 440 may convert UV light into visible light. Similar to the filter layer 250 shown in FIG. 2, the filter layer 450 may block visible light and/or IR light but allow UV light to pass therethrough. Therefore, the photo detectors 222 may sense visible light in the visible light sensing section 212 and sense UV light in the UV sensing section 214.

The image sensor chip 400 may further include an array of microlens 226 formed on the color filters 222 and the filter layer 250, and a package cover 230 attached to a top surface of the array of microlens 226.

As compared with the image sensor chip 200 shown in FIG. 2, the chip 400 is more compact because the UV coating layer 440 and the filter layer 450 are combined in the image sensor cells 420 and thus the chip 400 has a smaller overall thickness. This configuration also provide better protection for the UV coating layer 440 and the filter layer 450 since they are embodied in the image sensor cells 420. In addition, the UV coating layer 440 is positioned more close to the photo detectors 222, and more of visible light emitted from the UV coating layer 440 will be sensed by the photo detectors 222 therebelow, thus increasing efficiency and accuracy of the UV detection. In some embodiments, the filter layer 450 may be omitted.

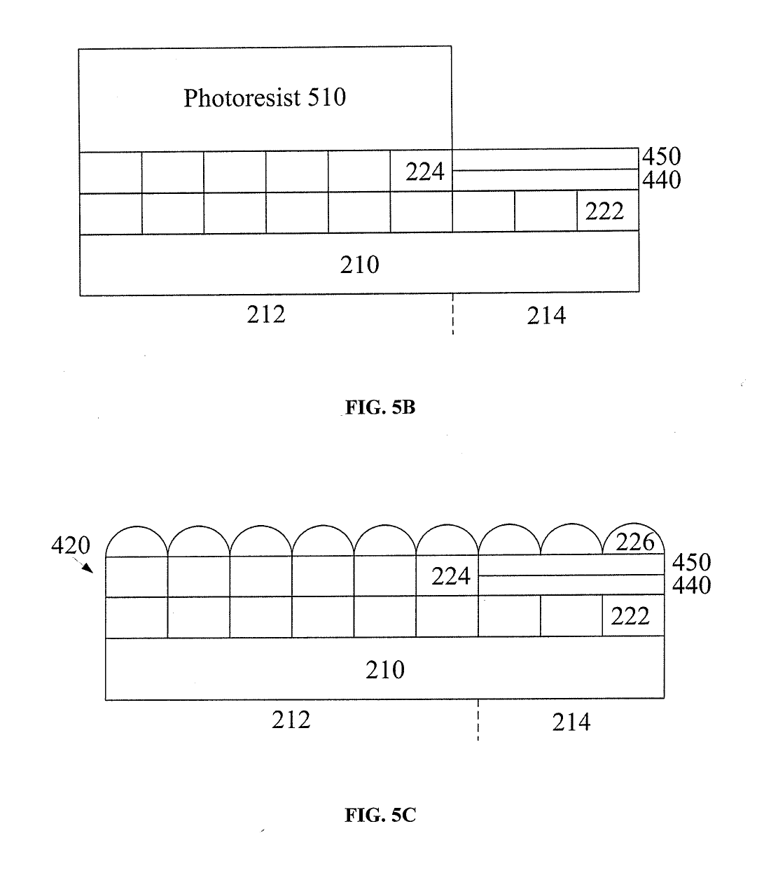

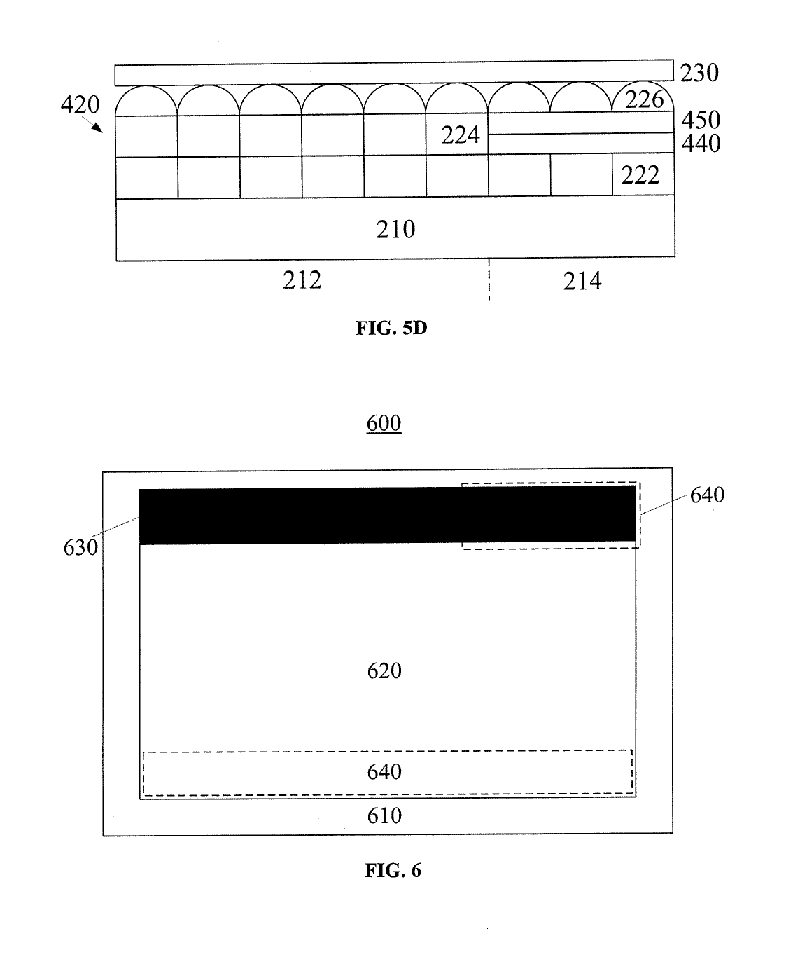

FIGS. 5A-5D are respectively process diagrams showing a method of implementing the single chip image sensor 400 as shown in FIG. 4, in accordance with another exemplary embodiment of the present invention. For convenience and concision of explanation, the process begins with the structure of FIG. 3A.

Referring to FIG. 5A, a plurality of color filters 224 are formed on the photo detectors 222 in the visible light sensing section 212, but not on the photo detectors 222 in the visible light sensing section 214. The color filters 224 are then masked by a photoresist pattern 510 exposing the photo detectors 222 in the visible light sensing section 214.

In FIG. 5B, a UV coating layer 440 and a filter layer 450 may be formed, for example, by an inkjet or screen printing process, on the photo detectors 222 in the visible light sensing section 214. The UV coating layer 440 and the filter layer 450 may be dimensioned so that a top surface of the filter layer 450 is substantially flush with the top surface of the color filters 224 in the visible light sensing section 212.

Next, referring to FIG. 5C, the photoresist pattern 510 may be removed, leaving a flat surface of the resulting structure. Then, an array of microlens 226 are formed on the flat surface, thereby completing a plurality of sensor cells 420. In some embodiments, the array of microlens 226 may be formed by a photoresist refow process, or a grey mask process. Then, a package cover 230 is attached to the top surface of the array of microlens 226, completing the single chip image sensor of FIG. 5D.

In some embodiments, the step of forming the filter layer 450 may be omitted, and the microlens 226 may be formed directly on the UV coating layer 440. In this case, the color filters 224 and the UV coating layer 440 may be dimensioned so that their upper surfaces are substantially flush with each other to provide a flat surface for forming the array of microlens 226 thereon.

In the above embodiments, all the image sensor cells, or at least all the photo detectors 222 are formed to be sensitive to visible light, so all the photo detectors 222 may be formed in a single process in the visible light sensing section 212 and the UV sensing section 214. The UV light is sensed by the UV coating layer 240, 440 converting the UV light to the visible light. Therefore, no additional readout circuit is needed to read the UV sensor data. The single chip image sensor of the embodiments can re-use the existing readout circuits from conventional visible light image sensor chip to save design area and power consumption.

In some embodiments, the photo detectors 222 in the visible light sensing section 212 may be still designed to be sensitive to visible light, while the photo detectors 222 in the UV sensing section 214 may be designed to be sensitive to UV light. For example, the UV sensing section 214 of the substrate 210 may be doped with some special materials to make the photo detectors formed therein sensitive to UV light. An example of such special materials includes carbon, which may be doped into a Si substrate to form SiC. As known, Si has a band gap of 1.1 eV and it is suitable for forming photo detectors sensitive to visible light, and SiC has a larger band gap of about 3.25 eV and it is suitable for forming photo detectors sensitive to UV light. By doping with C, the photo detectors 222 in the UV sensing section 214 may be enabled to sense UV light directly. In this case, the UV coating layer 240, 440 and the filter layer 250, 450 may be removed.

Referring back to FIG. 1, the visible light image sensor 120 and the UV sensor 130 are shown separated from each other on the substrate 110. In this case, an individual readout circuit is needed for the UV sensor 130. It adds some additional area and cost to the whole chip 100, but also brings more flexibility to run normal visible images and UV sensor on the same chip without affecting each other. For example, the UV sensor 130 may operate to detect UV radiation, while the visible light image sensor 120 turns off, or vice versa.

FIG. 6 shows some other layout designs for the visible light image sensor (including sensor cells in the visible light sensing section 212) and the UV sensor (including sensor cells in the UV sensing section 214). Referring to FIG. 6, a visible light image sensor chip 600 may conventionally include a normal sensing region 620 and a black region 630 that occupies a rectangular region on a substrate 610. In the black region 630, sensor cells are shielded by an optical black layer, for example, an opaque metal layer. Such cells provide a reference signal to indicate a black level when outputting signal from the normal sensing region 620. The black level may fluctuate in response to environment variation, for example, temperature variation. By providing the black region 630, fluctuation of signals from the normal sensing region 620 due to the black level may be prevented or reduced.

In some embodiments, an UV sensing region 640 may use a part of the normal sensing region 620, for example, an edge part thereof. In this case, the normal sensing region 620 (here refers to its remaining part) and the UV sensing region 640 together may form a rectangular region, and all the sensor cells, including those in the normal sensing region 620 and those in the UV sensing region 640, form an array in rows and columns. In this case, it is very convenient to readout and show both visible and UV images, and the chip 600 may re-use a conventional readout circuit.

In some embodiments, the UV sensing region 640 may use a part of the black region 630. As disclosed, the black region 630 provides a reference signal to indicate the black level. Normally, the reference signal is an averaged value of signals from respective sensor cells in the black region 630. So, some of the sensor cells in the black region 630 may be used to sense UV light without substantively affecting accuracy of the black level sensed by the black region 630. To this end, a part of the optical black layer may be removed and replaced by the UV coating layer as discussed above. As a result, the chip 600 can provide UV data from this part without affecting the visible light image data from the normal sensing region 620.

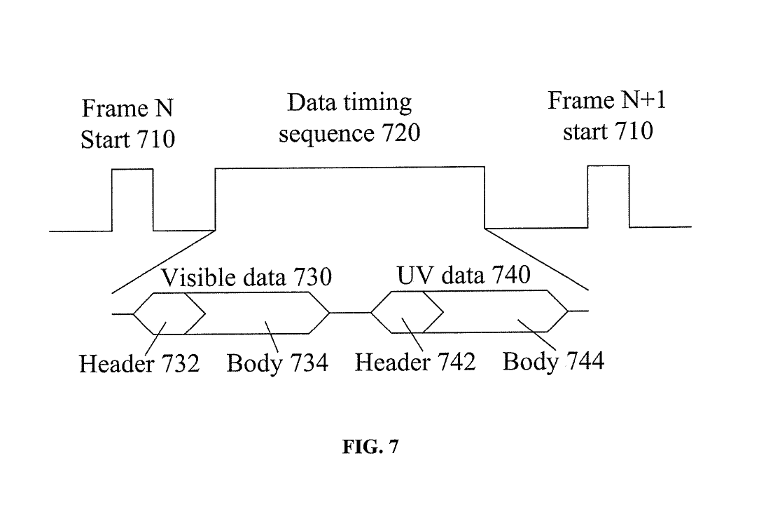

FIG. 7 shows an example of the data transmission format combining visible and UV image data. The sensor data are normally transmitted frame by frame, with a frame start signal 710 at the beginning of each frame. The content of each frame, including visible image data and UV image data, is transmitted subsequently during a data timing sequence 720. Within the sequence 720, the visible image data 730 and the UV image data 740 may be transmitted sequentially. In some embodiments, the visible image data 730 is transmitted first, and in some embodiments, the UV image data 740 is transmitted first. The visible image data 730 includes a data header 732 at its beginning to provide information such as data type, frame rate, gain, average value, etc., about the visible image data 730, and a following data body 734. Also, the UV image data 740 includes a data header 742 at its beginning to provide information such as data type, frame rate, gain, average value, etc., about the UV image data 740, and a following data body 744.

FIG. 7 merely shows an example to combine data from visible light image and UV data into one sequence, and the invention is not limited thereto. In other words, any variations of the data sequence combining the visible light image data and the UV image data are possible.

Any of the single chip image sensors provided in the above embodiments may be used in a digital camera or be integrated as a camera module in an electronic device, for example, a mobile electronic device such as a cell phone, a tablet, a laptop, a personal digital assistant (PDA), and the like. The single chip image sensor may be also used in any other electronic devices that have an imaging or light detection function.

The single chip image sensor as discussed in the above embodiments may operate in multiple possible modes. For example, in a mode 1, the single chip image sensor may output only normal visible light image. In a mode 2, the single chip image sensor may output an UV image only. In a mode 3, the single chip image sensor may output a statistic value of an UV image only. The statistic value of the UV image may have different options according to the application requirements. For example, it may be an average value, a max value, a medium value, a standard deviation, or the like of signals from respective UV sensor cells. In some embodiments, data from multiple exposures, multiple gains may be combined into one value to realize a higher dynamic range data as the final UV information. In a mode 4, the single chip image sensor may output a visible light image and an UV image at the same time. In a mode 5, the single chip image sensor may output a visible light image and a statistic value of an UV image at the same time. The operation mode of the single chip image sensor may be determined according to the application requirements or according to a user input. The single chip image sensor may also switch between the multiple modes.

One typical example of using the UV function of the single chip image sensor is to monitor outdoor UV radiation strength. One possible way to use it is to point the sensor directly to the sun and slightly move its angle for a while. An algorithm on-chip or in the device system will analyze the data and report a representative value, e.g., a max value obtained during the test. Alternatively, the user can point to a test target, e.g., a hand, a standard test chart, etc., and read the UV strength in that way. Interpretation of the test results from different test method may be different too. The product maker can provide guidance of how to interpret the data based on standard test results.

In the above embodiments, the single chip image sensor has both visible light image and UV light detection ability. In some embodiments, the single chip image sensor may be also formed as a UV sensor. In this case, the UV coating layer will cover all the photo detectors on the substrate, and the UV sensor may output an UV image. Such embodiments provide a UV sensor with a simple structure, and the UV sensor may be implemented by a process similar to that for making a visible light image sensor except that a UV coating layer is applied. The UV sensor may be used in a UV camera or be integrated as a separate module in any other electronic devices.

In the foregoing specification, embodiments of the present invention have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicant to be the scope of the invention, is the literal and equivalent scope of the set of claims that issue from this application, in the specific form in which such claims issue, including any subsequent correction.

1. A single chip image sensor, comprising:
a first plurality of sensor cells provided on a substrate, the first plurality of sensor cells each including a photo detector sensitive to visible light, and
a UV coating layer provided for the first plurality of sensor cells to convert incident UV light to visible light.

2. The single chip image sensor of claim 1, further comprising:
a second plurality of sensor cells provided on the substrate, the second plurality of sensor cells each also including a photo detector sensitive to visible light.

3. The single chip image sensor of claim 1, further comprising:
a filter film disposed on the UV coating layer to block incident visible and infrared lights.

4. The single chip image sensor of claim 2, further comprising:
a package cover disposed over the first and second plurality of sensor cells.

5. The single chip image sensor of claim 4, wherein the UV coating layer is provided on a portion of the package cover that covers the first plurality of sensor cells.

6. The single chip image sensor of claim 4, wherein the UV coating layer is provided between the package cover and the first plurality of sensor cells.

7. The single chip image sensor of claim 2, wherein the first and second plurality of sensor cells each further comprises:
a color filter formed on the photo detector to allow light of a particular color to pass therethrough, and
a micro-lens formed on the color filter to focus incident light onto the photo detector.

8. The single chip image sensor of claim 7, wherein the color filter includes a red, green or blue filter.

9. The single chip image sensor of claim 7, wherein the UV coating layer is formed within the first plurality of sensor cells.

10. The single chip image sensor of claim 9, wherein the color filters in the first plurality of sensor cells are replaced by the UV coating layer.

11. The single chip image sensor of claim 2, wherein the first and second plurality of sensor cells are arranged in an array of a rectangular shape, and the first plurality of sensor cells are arranged along a side of the rectangular shape.

12. The single chip image sensor of claim 11, wherein the second plurality of sensor cells includes a black region where the sensor cells are covered by a black layer so as to sense a dark current, and the first plurality of sensor cells and the second plurality of sensor cells in the black region are arranged along a same side of the rectangular shape.

13. The single chip image sensor of claim 2, wherein the second plurality of sensor cells are arranged in a rectangular region that is separated from or abuts a rectangular region where the first plurality of sensor cells are arranged.

14. An electronic device including a single chip image sensor comprising:
a first plurality of sensor cells provided on a substrate, the first plurality of sensor cells each including a photo detector sensitive to visible light, and
a UV coating layer provided for the first plurality of sensor cells to convert incident UV light to visible light.

15. The electronic device of claim 14, further comprising:
a second plurality of sensor cells provided on the substrate, the second plurality of sensor cells each also including a photo detector sensitive to visible light.

16. The electronic device of claim 15, further comprising:
a filter film disposed on the UV coating layer to block incident visible and infrared lights.

17. The electronic device of claim 15, further comprising:
a package cover disposed over the first and second plurality of sensor cells, wherein the UV coating layer is disposed above or below the package cover.

18. The electronic device of claim 14, wherein the electronic device is one of a cell phone, a tablet, a laptop, a personal digital assistant (PDA), a wearable device, a smart watch, or a camera.

19. A method of making a single chip image sensor, comprising:
forming a first plurality of sensor cells on a substrate, the first plurality of sensor cells each including a photo detector sensitive to visible light; and
providing a UV coating layer for the first plurality of sensor cells, the UV coating layer being capable of converting incident UV light to visible light.

20. The method of claim 19, further comprising:
forming a second plurality of sensor cells on the substrate, the second plurality of sensor cells each also including a photo detector sensitive to visible light.
